(19) United States
(12) Patent Application Publication
(10) Pub. No.: US 2024/0222111 A1
(43) Pub. Date: Jul. 4, 2024

(54) METHODS FOR SELECTIVELY FORMING A DIELECTRIC LAYER ON A METALLIC SURFACE RELATIVE TO A DIELECTRIC SURFACE

(71) Applicant: ASM IP Holding B.V., Almere (NL)

(72) Inventors: Viraj Madhiwala, Heverlee (BE); Eva E. Tois, Espoo (FI); Daniele Chiappe, Freiburg (DE); Marko Tuominen, Helsinki (FI)

(21) Appl. No.: 18/396,357

(22) Filed: Dec. 26, 2023

Related U.S. Application Data
(60) Provisional application No. 63/478,036, filed on Dec. 30, 2022.

(51) Int. Cl. H01L 21/02

(52) U.S. Cl. CPC H01L 21/0228; H01L 21/02046; H01L 21/0206; H01L 21/02178; H01L 21/02205; H01L 21/02304; H01L 21/02312

(57) ABSTRACT

Methods for selectively forming a dielectric layer on a metallic surface relative to a dielectric surface are disclosed. The disclosed selective formation methods include selective passivation processes, and selective deposition processes.

### CROSS-REFERENCE TO RELATED APPLICATION(S)

This application claims the benefit of U.S. Provisional Application 63/478,036 filed on Dec. 30, 2022, the entire contents of which are incorporated herein by reference.

### FIELD OF INVENTION

The present disclosure generally relates to the field of semiconductor processing methods and related structures, and to the field of device and integrated circuit manufacture. More particularly, the present disclosure relates generally to methods for selectively forming a dielectric layer on a metallic surface relative to a dielectric surface.

### BACKGROUND OF THE DISCLOSURE

In some applications, it may be desirable to form a dielectric layer only on certain areas of a substrate. Typically, such discriminating results are achieved by depositing a continuous dielectric layer and subsequently patterning the continuous dielectric layer using lithography and etch steps. Such lithography and etch processes may be time consuming, expensive, and do not offer the precision required for many applications.

A possible solution is the use of selective deposition processes, whereby a dielectric layer is formed only in the desired areas thereby eliminating the need for subsequent patterning steps. Selective deposition processes may take a number of forms, including, but not limited to, selective dielectric deposition on dielectric surfaces (DoD), selective dielectric deposition on metallic surfaces (DoM), selective metal deposition on dielectric surfaces (MoD), and selective metal deposition on metallic surfaces (MoM).

Selective deposition on metallic surfaces (i.e., DoM, or MoM) may be of interest for providing simplified methods for selectively forming a dielectric layer on a metallic surface without the need for complex patterning and etch steps. However, the surface properties of metallic surfaces may negatively impact the selective formation of a dielectric layer on metallic surfaces. Accordingly, improved methods are desired for selectively forming dielectric layers on metallic surfaces relative to dielectric surfaces.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

In particular the present disclosure includes methods for selectively forming a dielectric layer on a metallic surface relative to dielectric surface. The methods can include, seating a substrate including a metallic surface and a dielectric surface within a reaction chamber, selectively passivating the metallic surface relative to the dielectric surface, selectively depositing a passivation layer on the dielectric surface relative to the metallic surface, and selectively depositing a dielectric layer on the metallic surface relative to the passivation layer.

In some embodiments, the methods can also include, performing a preclean of the substrate prior to selectively passivating the metallic surface relative to the dielectric surface.

In some embodiments, the preclean of the substrate comprises, removing a native oxide from the metallic surface.

In some embodiments, removing the native oxide comprises, contacting the substrate with a vapor phase etchant.

In some embodiments, the native oxide comprises a copper oxide (CuOₓ) and the vapor phase etchant is selected from the group consisting of acetic acid, and hexafluoroacetylacetone (H(hfac)).

In some embodiments, selectively passivating the metallic surface relative to the dielectric surface further comprises, contacting the metallic surface with a silylating agent.

In some embodiments, the silylating agent comprises 1,2-bis(triethoxysilyl)ethane (BTESE).

In some embodiments, selectively depositing the passivation layer on the dielectric surface relative to the metallic surface further comprises, performing a plurality of deposition cycles of a molecular layer cyclical deposition process in which the substrate is alternately and sequentially contacted with a first vapor phase organic precursor, and a second vapor phase organic precursor

In some embodiments, the methods also include, performing an etch back process for removing any contaminants from the metallic surface post passivation layer selective deposition.

In some embodiments, the etch back process comprises, contacting the metallic surface with reactive species generated from a plasma formed from a gas comprising hydrogen and argon.

In some embodiments, selectively depositing a dielectric layer on the metallic surface relative to the passivation layer comprises, selectively depositing a metal oxide from vapor phase reactants on the metallic surface relative to the passivation layer.

In some embodiments, the metal oxide comprises aluminum oxide

In some embodiments, the aluminum oxide is deposited using an aluminum precursor comprising, trimethyl aluminum (TMA), dimethylaluminumchloride, aluminum trichloride (AlCl3), dimethylaluminum isopropoxide (DMAI), tris(tertbutyl)aluminum (TTBA), tris(isopropoxide)aluminum (TIPA) or triethyl aluminum (TEA)

In some embodiments, the aluminum oxide is deposited using an aluminum precursor comprising dimethylaluminum isopropoxide (DMAI).

In some embodiments, the aluminum oxide is deposited by an ALD process comprising, alternately and sequentially contacting the substrate with a first reactant comprising trimethyl aluminum (TMA), dimethylaluminumchloride, aluminum trichloride (AlCl3), dimethylaluminum isopropoxide (DMAI), tris(tertbutyl)aluminum (TTBA), tris(isopropoxide)aluminum (TIPA) or triethyl aluminum (TEA), and a second reactant comprising water.

In some embodiments, the aluminum oxide is deposited by an ALD process comprising, alternately and sequentially contacting the substrate with a first reactant comprising trimethyl aluminum (TMA), dimethylaluminumchloride, aluminum trichloride (AlCl3), dimethylaluminum isopropoxide (DMAI), tris(tertbutyl)aluminum (TTBA), tris(isopropoxide)aluminum (TIPA) or triethyl aluminum (TEA), and a second reactant comprising water.

In some embodiments, the aluminum oxide is deposited by a chemical vapor deposition process comprising contacting the substrate with dimethylaluminum isopropoxide (DMAI) and a second reactant comprising water.

In some embodiments, the method any also include, selectively removing the passivation layer thereby re-exposing the dielectric surface.

In some embodiments, the selectively removing the passivation layer comprises, contacting the passivation layer with reactive species generated from a plasma formed from a gas comprising hydrogen and argon.

Additional methods of the present disclosure can include methods for selectively forming an aluminum oxide dielectric layer on a metallic surface relative to dielectric surface. The methods can include, seating a substrate including a metallic surface and a dielectric surface within a reaction chamber, contacting the substrate with a silylating agent to selectively passivate the metallic surface relative to the dielectric surface, selectively depositing a passivation layer on the dielectric surface relative to the metallic surface by performing a plurality of deposition cycles of a molecular layer cyclical deposition process in which the substrate is alternately and sequentially contacted with a first vapor phase organic precursor, and a second vapor phase organic precursor. The methods can also include, contacting the metallic surface with reactive species generated from a plasma formed from a gas comprising one or more of hydrogen and argon, thereby removing any contaminants from the metallic surface. The methods can also include, selectively depositing an aluminum oxide on the metallic surface relative to the passivation layer by contacting the substrate with dimethylaluminum isopropoxide (DMAI) and a second reactant comprising water, and selectively removing the passivation layer by contacting the passivation layer with reactive species generated from a plasma formed from a gas comprising one or more of hydrogen and argon.

For the purpose of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates an exemplary process flow for selectively forming a dielectric layer on a metallic surface relative to a dielectric surface in accordance with at least one embodiment of the present disclosure;

FIG. 2 illustrates an exemplary sub-process flow for selectively depositing a passivation layer on a dielectric relative to a metallic surface in accordance with at least one embodiment of the present disclosure; and

FIG. 3 illustrates an exemplary sub-process flow for selectively depositing a dielectric layer on a metallic surface relative to a passivation layer in accordance with at least one embodiment of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices, and apparatus provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for selectively forming a dielectric layer on a metallic surface relative to a dielectric surface, the dielectric layers being suitable and advantageous in a variety of applications. Methods can be used, for example, for the selective formation of metal oxide dielectric layers on a metallic surfaces. However, unless noted otherwise, the invention is not necessarily limited to such examples.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e. ceramic fibers or polymer fibers). Continuous substrates may also comprise carriers or sheets upon which non-continuous substrates are mounted.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a “structure” can be or include a substrate as described herein. Structures can include one or more layers overlying or within the substrate, such as one or more layers formed according to a method as described herein. Full devices or partial device portions can be included within or on structures.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), molecular layer deposition (MLD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

As used herein, the term “molecular layer deposition” (MLD) may refer to a vapor deposition process in which deposition cycles, preferably a plurality of consecutive deposition cycles, are conducted in a process chamber. Typically, during each cycle an organic precursor is chemisorbed to a deposition surface (e.g., a substrate surface or a previously deposited underlying surface such as material from a previous MLD cycle), typically forming a single molecular layer that does not readily react with additional organic precursor (i.e., a self-limiting reaction). Thereafter, if necessary, another precursor (e.g., another organic precursor) may subsequently be introduced into the process chamber for use in forming the desired organic material on the deposition surface. Further, purging steps may also be utilized during each cycle to remove excess organic precursor from the process chamber and/or remove reaction byproducts from the process chamber after formation of the desired organic material.

As used herein, the term “metallic surface” may refer to surfaces including a metallic component, including, but not limited to, metal surfaces, metal oxide surfaces, metal silicide surfaces, metal nitride surfaces, metal carbide surfaces, and mixtures thereof. The term “metallic surface” may can also include a surface of a native oxide of a metallic material.

As used herein, the term “dielectric surface” may refer a surface of dielectric material, including, but not limited to, silicon containing dielectric materials, such as, for example, silicon oxides, silicon nitrides, silicon oxynitrides, silicon oxycarbides, and mixtures thereof. In addition, the term “dielectric surface” may also refer to a surface of metal oxide material, or metal nitride material, or low dielectric constant material (a low-k material), or high dielectric constant material (a high-k material).

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. This notwithstanding, the chemical compound, substance, or composition of matter may, in some embodiments, comprise other components as trace elements or impurities, apart from the components that are listed.

A number of example materials are given throughout the embodiments of the current disclosure, it should be noted that the chemical formulas given for each of the example materials should not be construed as limiting and that the non-limiting example materials given should not be limited by a given example stoichiometry.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The embodiments of the disclosure may include methods for selectively forming a dielectric layer on a substrate comprising a metallic surface and a dielectric surface. In particular, the embodiments of the disclosure may comprise, selectively forming a dielectric layer one a metallic surface relative to a dielectric surface and may include selective dielectric-on-metal formation processes. The selective formation of a dielectric layer on a metallic surface may be permitted by selectively passivating the metallic surface with a passivating agent and subsequently selectively depositing a passivation layer on the dielectric surface without forming the passivation layer on the metallic surface. Subsequently a dielectric layer, can be selectively deposited on the metallic surface which is not covered with the passivation layer.

Non-limiting example applications for the selective processes of the current disclosure may include, selectively forming a dielectric layer, such as, a metal oxide dielectric layer for use as hard masks, or etch stop layers on various metals. In addition, the selectively formed dielectric films of the present disclosure can be utilized as encapsulation layers on various metals. In further applications, the dielectric-on-metal selective processes of the present disclosure may be utilized in the fabrication of novel memory and logic applications.

The skilled artisan will appreciate that selective deposition can be fully selective or partially selective. A partially selective process can result in fully selective layer by a post-deposition etch that removes all of the deposited material from over surface B without removing the entirety of the deposited material from over surface A. Because a simple etch back process can leave a fully selective structure without the need for expensive masking processes, the selective deposition need not be fully selective in order to obtain the desired benefits.

Selectivity of deposition on surface A relative to surface B can be given as a percentage calculated by [(deposition on surface A)−(deposition on surface B)]/(deposition on the surface A). Deposition can be measured in any of a variety of ways. For example, deposition may be given as the measured thickness of the deposited material, or may be given as the measured amount of material deposited. In embodiments described herein, selective deposition of a passivation layer, can be conducted on a dielectric surface (A) relative to a metallic surface (B). Subsequently, a dielectric layer may be selectively deposited on a metallic surface (A) relative to a passivation layer (B).

In some embodiments, the selectivity of the selective deposition of the passivation layer on a dielectric surface (relative to a metallic surface) and/or the selectivity of a dielectric layer on a metallic surface (relative to a passivation layer) is greater than about 10%, or greater than about 50%, or greater than about 75%, or greater than about 85%, or greater than about 90%, or greater than about 93%, or greater than about 95%, or greater than about 98%, or greater than about 99%, or even greater than about 99.5%.

In some embodiments, deposition only occurs on the first surface and does not occur on the second surface. In some embodiments, deposition on surface A of the substrate relative to surface B of the substrate is at least about 80% selective, which may be selective enough for some particular applications. In some embodiments, the deposition on the surface A of the substrate relative to surface B of the substrate is at least about 50% selective, which may be selective enough for some particular applications. In some embodiments the deposition on surface A of the substrate relative to the surface B of the substrate is at least about 10% selective, which may be selective enough for some particular applications. The skilled artisan will appreciate that a partially selective process can result in a fully selective structure by a post-deposition etch that removes all of the deposited material from over surface B without removing the entirety of the deposited material from over surface A.

In some embodiments, a passivation layer deposited on a dielectric surface may have a thickness less than 50 nanometers, or less than 20 nanometers, or less than 10 nanometers, or less than 5 nanometers, or less than 3 nanometers, or less than 2 nanometers, or less than 1 nanometer, while a ratio of material deposited on the dielectric surface relative to the metallic surface may be greater than or equal to 200:1, or greater than or equal to 100:1, or greater than or equal to 50:1, or greater than or equal to 25:1, or greater than or equal to 20:1, or greater than or equal to 15:1, or greater than or equal to 10:1, or greater than or equal to 5:1, or greater than or equal to 3:1, or greater than or equal to 2:1.

In some embodiments the selectivity of the selective formation processes described herein may depend on the material compositions of the materials which define the metallic surfaces and the dielectric surfaces.

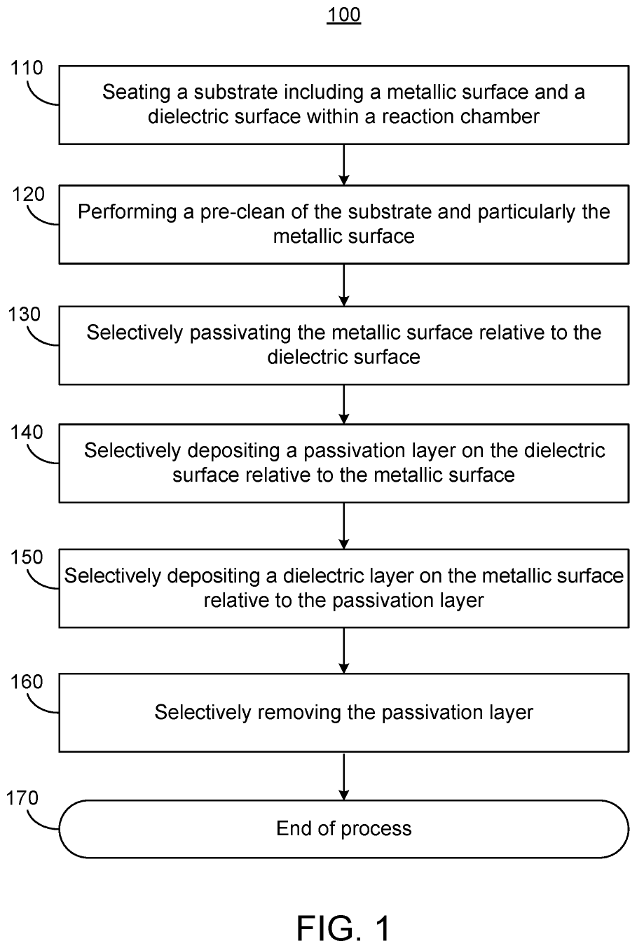

The embodiments of the disclosure may be understood in greater detail with reference to FIG. 1 which illustrates an exemplary process 100 for selectively forming a dielectric layer on a metallic surface relative to a dielectric surface. The exemplary process 100 includes the process step 110 comprising, seating a substrate including a metallic surface and a dielectric surface within a reaction chamber.

In some embodiments, the metallic surface comprises a metal. In some embodiments, the metal is selected from a group consisting of copper (Cu), cobalt (Co), ruthenium (Ru), tungsten (W), titanium (Ti), aluminum (Al), tantalum (Ta) and molybdenum (Mo). In some embodiments, the metallic surface comprises an elemental metal. In some embodiments, the metallic surface consists essentially of, or consists of, elemental metal

In some embodiments, the metal or metallic surface may comprise metal, metal oxides, and/or mixtures thereof. In some embodiments the metal or metallic surface may comprise surface oxidation. In some embodiments the metal or metallic material of the metal or metallic surface is electrically conductive with or without surface oxidation. In some embodiments, metal or a metallic surface comprises one or more transition metals. In some embodiments the metal or metallic surface comprises one or more of TiN, W, Co, Cu, Ir or TaN. In some embodiments the metal or metallic surface comprises one or more of Al, Ni, Nb, Fe. In some embodiments the metal or metallic surface comprises one or more noble metals, such as Ru. In some embodiments, the metal or metallic surface comprises a conductive metal oxide, nitride, carbide, boride, or combination thereof. For example, the metal or metallic surface may comprise one or more of RuOx, NbCx, NbBx, NiOx, CoOx, NbOx, WNCx, TaN, or TiN.

In some embodiments a metal or metallic surface comprises cobalt (Co), copper (Cu) or tungsten (W). In some embodiments, the metal or metallic surface may be any surface that can accept or coordinate with the passivating agents described herein and utilized the selective deposition process of the present disclosure.

In some embodiments, the dielectric surface comprises a silicon-based dielectric surface selected from the group consisting of SiO₂, SiN, SiOC, SiON, SiOCN and mixtures thereof. In some embodiments, a dielectric surface comprises a metal oxide selected from the group consisting of aluminum oxide, hafnium oxide and zirconium oxide. It should be noted, the term dielectric is used in the description herein for the sake of simplicity in distinguishing from another surface, namely a metal or a metallic surface. It will be understood by those skilled in the art that not all non-conducting surfaces are dielectric surfaces. For example, the metal or metallic surface may comprise an oxidized metal surface that is electrically non-conducting or has a very high resistivity.

The process step 110 (FIG. 1) may further comprise loading the substrate into a suitable reaction chamber and seating the substrate within the reaction chamber. The reaction chamber may be configured for performing all, or a portion, of the remaining process steps of exemplary process 100.

Reactors and associated reaction chamber(s) capable of the selective formation of a dielectric layer on a metallic surface relative to a dielectric surface can be used to perform the processes of the present disclosure. Such reaction chambers may include atomic/molecular layer deposition (ALD/MLD) reaction chambers, plasma enhanced atomic layer deposition (PEALD) reaction chambers, as well as chemical vapor deposition (CVD) reaction chambers equipped with appropriate equipment and means for providing precursors. According to some embodiments a showerhead reaction chamber may be used. According to some embodiments a plasma reaction chamber, such as PEALD reaction chamber, may be used. In such embodiments, the plasma may be direct, remote, or in the near vicinity of the substrate. In some embodiments the reactor is a spatial ALD reactor, in which the substrates moves or rotates during processing.

In some embodiments a batch reactor may be used. In some embodiments, a vertical batch reactor is utilized in which the boat rotates during processing. For example, a vertical batch reactor may comprise, a reaction chamber and an elevator constructed and arranged to move a boat configured for supporting a batch of between 10 to 200 substrates in or out of the reaction chamber.

The exemplary processes of the present disclosure can optionally be carried out in a reactor and associated reaction chambers connected to a cluster tool. In a cluster tool, because each reaction chamber is dedicated to one type of process, the temperature of the reaction chamber in each module can be kept constant, which improves the throughput compared to a reaction chamber in which the substrate is heated up to the process temperature before each run. Additionally, in a cluster tool it is possible to reduce the time to pump the reaction space to the desired process pressure levels between substrates.

Once the substrate has been loaded and seated within in a suitable reaction chamber, the substrate may be heated to a process temperature (e.g., the substrate temperature) for performing the process steps of the present disclosure. In some embodiment, the process temperature may remain constant for the all process step of the exemplary process 100 (FIG. 1). In alternative embodiments, the process temperature may be altered depending on the needs of the specific process step being performed.

In some embodiments, a process temperature employed for selectively passivating a metallic surface relative to the dielectric surface (step 130) may be between 50° C. and 500° C., or between 100° C. and 300° C. In some embodiments, a process temperature employed for selectively depositing a passivation layer on the dielectric surface relative to the metallic surface (step 140) can be less 250° C., or less than 200° C., or less than 150° C., or less than 100° C., or less than 80° C., or between 150° C. and 250° C., or between 170° C. and 210° C., and subsequently the passivation layer may be heat-treated at a temperature of about 190° C. or higher (such as 200° C. or 210° C.). In some embodiments, a process temperature employed for selectively depositing a dielectric layer on a metallic surface relative to the passivation layer (step 150) can be less 400° C., or less than 350° C., or less than 250° C., or less than 150° C., or less than 100° C., or between 100° C. and 400° C., or between 150° C. and 350° C. All of the above process temperatures can also be altered depending on the composition of the substrate surfaces, the composition of the passivation layer, and the selectively deposited dielectric layer, for example.

In addition to controlling process temperature the pressure within the reaction chamber may also be controlled to a pressure between 10e⁻⁶ Torr and 1000 Torr, or between 10e⁻⁵ Torr and 760 Torr, or between 10e⁻⁴ and 100 Torr, or even between 0.01 Torr and 50 Torr.

The exemplary process 100 can proceed by means of a process step 120 comprising, performing a preclean of the substrate prior to selectively passivating the metallic surface. In some embodiments, the preclean of the substrate comprises, removing a native oxide from the metallic surface. In some embodiments, removing the native oxide comprises, a chemical-mechanical-polishing process. In some embodiments, removing the native oxide comprises, contacting the substrate with a vapor phase etchant. For example, in embodiments wherein the native oxide comprises a copper oxide (CuOₓ), the vapor phase etchant can be selected from the group consisting of acetic acid, and hexafluoroacetylacetone (H(hfac)).

In additional embodiments, the substrate may be precleaned (or pretreated) prior to or at the beginning of the selective formation processes by subjected the substrate to a plasma cleaning process. In some embodiments, a plasma cleaning process may not include ion bombardment, or may include relatively small amounts of ion bombardment. For example, in some embodiments the substrate surfaces may be exposed to plasma, radicals, excited species, and/or atomic species prior to or at the beginning of the selective passivation. In some embodiments, the substrate surface may be exposed to hydrogen plasma, radicals, or atomic species prior to or at the beginning of the selective passivation. In some embodiments, the substrate surface may be thermally treated with exposure to hydrogen, ammonia, and mixtures thereof prior to or at the beginning of the selective passivation. In some embodiments, a pretreatment or cleaning process may be carried out in the same reaction chamber as the selective formation process of the present disclosure, however in some embodiments a pretreatment or cleaning process may be carried out in a separate reaction chamber, and the passivation process may also be conducted in a separate chamber from the subsequent selective deposition reaction chamber.

The exemplary process 100 can proceed by means of a process step 140 comprising, selectively passivating the metallic surface relative to the dielectric surface. In some embodiments, selectively passivating the metallic surface relative to the dielectric surface comprises, contacting the metallic surface with a passivation agent. For example, process step 140 can comprise providing a passivation agent into the reaction chamber in a vapor phase to selectively passivate the metallic surface prior to selectively forming a passivation layer on the dielectric surface relative to the metallic surface.

In some embodiments, the passivation agent can comprise, a silylating agent. In some embodiments, the silylating agent comprises 1,2-bis(triethoxysilyl)ethane (BTESE).

In some embodiments, the passivation agent can comprise alkane thiol chemistries, such as, for example, trimethylsilylthiol, dimethylsilanethiol, and methylsilanethiol, trifluoromethyl thiol, and methanethiol.

In some embodiments, the passivating agent may be an organic unsaturated alkane. In some embodiments, the organic alkane may contain less than or equal to 5 carbon atoms, less than or equal to 4 carbon atoms, less than or equal to 3 carbon atoms, less than or equal to 2 carbon atoms, or less than or equal to one carbon atom, or any range between any of these values. For example, in some embodiments organic alkanes that contain less than or equal to 5 carbon atoms include propanediene, butadiene and propene. In another example, in some embodiments haloalkanes that contain less than or equal to 5 carbon atoms include dichloromethane (DCM) and chloromethane.

In some embodiments, the passivating agents of the present disclosure include hydrophobic or otherwise non-reactive terminations facing away from the metallic surface being passivated.

Following selective passivation, the exemplary process 100 may further include the process step 140 comprising, selectively depositing a passivation layer on the dielectric surface relative to the metallic surface. In some embodiments, selectively depositing the passivation layer on the dielectric surface relative to the metallic surface further comprises, performing a plurality of deposition cycles of a molecular layer cyclical deposition process in which the substrate is alternately and sequentially contacted with a first vapor phase organic precursor, and a second vapor phase organic precursor

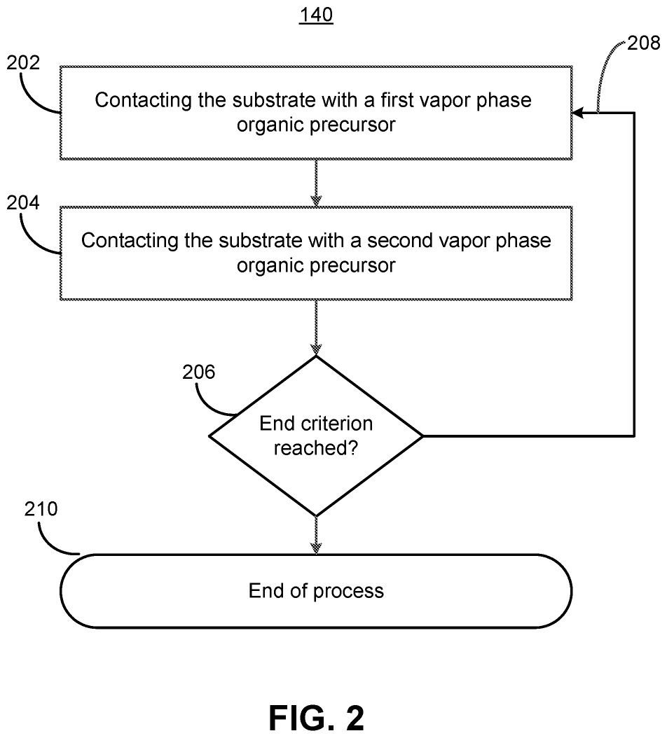

Methods for selectively forming a passivation layer by vapor deposition techniques are disclosed and described in U.S. Pat. No. 10,373,820, filed on Jun. 1, 2016, the entire disclosure of which is incorporated herein by reference for all purposes, and therefore such methods are briefly reviewed herein with reference FIG. 2, which illustrates an exemplary selective cyclical deposition process (step 140 and the associated sub-steps of process step 140) for selectively depositing a passivation layer on a dielectric surface relative to a metal surface.

In some embodiments, a process temperature employed for selectively depositing the passivation layer on the dielectric surface relative to the metallic surface (process 140 of FIG. 2) can be less 250° C., or less than 200° C., or less than 150° C., or less than 100° C., or less than 80° C., or between 150° C. and 250° C., or between 170° C. and 210° C., and subsequently the passivation layer may be heat-treated at a temperature of about 190° C. or higher (such as 200° C. or 210° C.).

Upon heating the substrate to the process temperature, the selective cyclical deposition process 140 (FIG. 2) may further comprise, contacting the substrate with a first vapor phase organic precursor (sub-step 202 of FIG. 2). In some embodiments, the first vapor phase organic precursor can comprise an organic reactant such as a diamine, such as, for example, 1,6-diaminohexane (DAH), or any other monomer with two reactive groups. In some embodiments, the first vapor phase organic precursor may comprise a diamine and may be vaporized to produce a first vapor phase organic precursor comprising a diamine vapor which is transported to the reaction chamber and contacts the substrate.

Upon contacting the substrate with the first vapor phase organic precursor (sub-step 202 of FIG. 2), the reaction chamber may be purged of any excess reactant and/or reaction by-products.

The selective cyclical deposition process 140 (FIG. 2) can continue with a sub-step 204 comprising, contacting the substrate with a second vapor phase organic precursor. For example, in some embodiments, the second vapor phase organic precursor can comprise an anhydride, such as furan-2,5-dione (maleic acid anhydride) and methods may comprise vaporizing the anhydride and transporting the anhydride vapor to the reaction chamber and contacting the substrate with the anhydride vapor. In some embodiments of the disclosure, the anhydride may comprise a dianhydride, e.g., pyromellitic dianhydride (PMDA), or any other monomer with two reactive groups which will react with the first vapor phase organic precursor.

Upon contacting the substrate with the second vapor phase organic precursor (sub-step 204), the reaction chamber may be again purged of any excess precursor and/or reaction by-products.

The exemplary selective cyclical deposition process 140 (FIG. 2) may continue via a decision gate 206, wherein the decision gate is dependent on reaching a predetermined end of process criterion, where if the end of process criterion is attained, the cyclical selective deposition process 140 terminates via the end of process sub-step 210, whereas if the end of process criterion is not attained then the selective cyclical deposition process 140 can continue via the cyclical process loop 208 and one or more further deposition cycles can be performed until the end criterion is successfully attained.

In some embodiments, the end criterion for ending the exemplary cyclical process 140 may comprise, reaching a predetermined thickness of the passivation layer on the dielectric surface relative to the metallic surface. In some embodiments, the end criterion for ending the exemplary selective cyclical deposition process 140 may comprise, performing a predetermined number of deposition cycles.

For example, if the end criterion is not satisfied, then the exemplary cyclical deposition process 140 (FIG. 2) may continue via the cyclical process loop 208 and one or more further deposition cycles may be performed by repeated performing the sub-step 202 and the sub-step 204. For example, in some embodiments, the selective cyclical deposition process 140 (FIG. 2) may comprise, from at least 10 to at most 30000 deposition cycles, or from at least 10 to at most 3000 deposition cycles, or from at least 10 to at most 1000 deposition cycles, or from at least 10 to at most 500 deposition cycles, or from at least 20 to at most 200 deposition cycles, or from at least 50 to at most 150 deposition cycles, or from at least 75 to at most 125 deposition cycles, for example 100 deposition cycles.

In some embodiments, the organic passivation layer can be selectively deposited on the dielectric surface relative to the metallic surface and may have an average thickness of less than 100 nanometers, or less 50 nanometers, or less than 20 nanometers, or less than 10 nanometers, or less than 5 nanometers, or less than 3 nanometers, or less than 2 nanometers, or less than 1 nanometer, or even between 1 nanometer and 100 nanometers.

In some embodiments, the ratio of material deposited on the dielectric surface relative to the metallic surface may be greater than or equal to 200:1, or greater than or equal to 100:1, or greater than or equal to 50:1, or greater than or equal to 25:1, or greater than or equal to 20:1, or greater than or equal to 15:1, or greater than or equal to 10:1, or greater than or equal to 5:1, or greater than or equal to 3:1, or greater than or equal to 2:1.

In some embodiments, the selectivity of the depositing passivation layer on a dielectric surface relative to the metallic surface can be greater than 10%, or greater than 50%, or greater than 75%, or greater than 85%, or greater than 90%, or greater than 93%, or greater than 95%, or greater than 98%, or greater than about 99%, or even greater than 99.5%. Therefore, in some embodiments, an organic passivation layer can be deposited preferentially on a first dielectric surface relative to a metal chalcogenide surface with a selectivity above 50%.

After selective deposition of the passivation layer (process step 140 of FIG. 1) the metallic surface may need to cleaned prior to proceeding with selective deposition of a dielectric layer on the metallic surface. Therefore, the methods of present disclosure may further include, performing an etch back process for removing any contaminants from the metallic surface. For example, the metallic surface can include contaminants from any residual passivation agent remaining on the metallic surface. In addition, the selective deposition of the passivation layer on the dielectric surface relative to the metallic can deposit some amount of the passivation layer on the metallic surface if the selective process has less than 100% selectivity. Since the passivation layer thickness is greater on the dielectric surface relative to the metallic, the etch back process can be controlled to remove all of the passivation layer on the metallic surface without removing all passivation layer from on the dielectric surface.

For example, an etch back process may comprise exposing the substrate to a plasma. In some embodiments, unwanted passivation layer can be removed by plasma comprising oxygen atoms, oxygen radicals, oxygen plasma, or combinations thereof. In some embodiments, the plasma may comprise hydrogen atoms, hydrogen radicals, hydrogen plasma, or combinations thereof. In some embodiments, the plasma may also comprise noble gas species, for example Ar or He species. In some embodiments the plasma may consist essentially of noble gas species. In some instances, the plasma may comprise other species, for example nitrogen atoms, nitrogen radicals, nitrogen plasma, or combinations thereof. In some embodiments, the plasma may comprise reactive species generated from a gas comprising hydrogen and argon.

In some embodiments, the etch back process may comprise exposing the substrate to an etchant comprising oxygen, for example O₃. In some embodiments, the substrate may be exposed to an etchant at a temperature of between about 30° C. and about 500° C., preferably between about 100° C. and about 400° C. In some embodiments, the etchant may be supplied in one continuous pulse or may be supplied in multiple shorter pulses.

After cleaning the metallic surface, the exemplary process 100 (FIG. 1) can further include the process step 150 comprising, selectively depositing a dielectric layer on the metallic surface relative to the passivation layer.

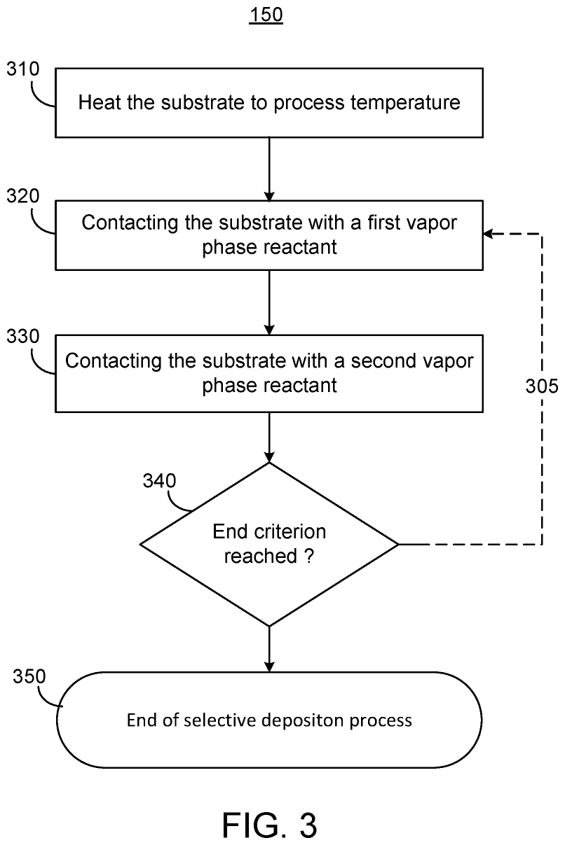

In more detail, an exemplary selective deposition process 150 and its constituent sub-steps, for selectively depositing a dielectric layer on the metallic surface relative to passivation layer are illustrated with reference to FIG. 3.

In some embodiments the selective deposition process 150 (FIG. 3) can comprise, heating the substrate to a process temperature of less than 400° C., or less than 350° C., or less than 250° C., or less than 150° C., or less than 100° C., or between 100° C. and 400° C., or between 150° C. and 350° C.

In some embodiments, the exemplary selective deposition process 150 (FIG. 3) can comprise a selective chemical vapor deposition (CVD) process. For example, a selective CVD process can comprise contacting the substrate with two or more volatile precursors which react and/or decompose on the substrate to form the dielectric layer. Unlike pure ALD, mutually reactive reactants are often simultaneously exposed to the substrate in CVD processes. Therefore, in such CVD embodiments, the exemplary process 150 (FIG. 3) can comprise contacting the substrate with a first vapor phase reactant (sub-step 320), and contacting the substrate with a second vapor phaser reactant (sub-step 330) simultaneously, or at least with a significant temporal overlap. In embodiments wherein the dielectric layer is selectively deposited by a CVD process, the decision gate 340, which determines the end criterion for halting the selective CVD process may be based on reaching a predetermined thickness of the dielectric layer, or alternatively the end criterion for halting the selective CVD process may be based on reaching a predetermined deposition time period. Upon reaching the predetermined end criterion the exemplary selective CVD may end via the end of selective deposition process step 350.

In embodiments, the dielectric layer comprises aluminum oxide. In such embodiments, the aluminum oxide can be deposited by a selective chemical vapor deposition process. In such embodiments, the selective CVD process can comprise contacting the substrate with dimethylaluminum isopropoxide (DMAI) and a second reactant comprising water.

In alternative embodiments, the exemplary selective deposition process 150 (FIG. 3) can comprise a selective atomic layer deposition (ALD) process. Therefore, in such embodiments, the selective ALD process can comprise the exemplary process 150 (FIG. 3) and can further include a selective cyclical deposition cycle comprising, contacting the substrate with a first vapor phase reactant (sub-step 320), subsequently purging the reaction chamber, contacting the substrate with a second vapor phaser reactant (sub-step 330), and again purging the reaction chamber. In embodiments wherein the dielectric layer is deposited by a selective ALD process, the deposition cycles may be repeated multiple times. For example, the exemplary process 150 illustrates a process cycle loop 305 denoting that the ALD deposition cycles can be repeated multiple times until the end criterion of the decision gate 340 is reached. It should be noted that the process loop 305 is illustrated as dashed line in FIG. 3 as this process may not be utilized when employing selective chemical vapor deposition processes.

In embodiments comprising selective ALD processes, the end criterion for the decision gate 340 can be based on reaching a predetermined thickness of the dielectric layer, or alternatively can be based on performing a predetermined number of deposition cycles. Upon reaching the predetermined end criterion the exemplary ALD process may end via the end of selective deposition process step 350.

In some embodiments of the disclosure, selectively depositing a dielectric layer on the metallic surface relative to the passivation layer comprises, selectively depositing a metal oxide from vapor phase reactants on the metallic surface relative to the passivation layer. In some embodiments, the metal oxide comprises a dielectric transition metal oxide. In some embodiments, the metal oxide comprises aluminum oxide, zirconium oxide, hafnium oxide, titanium oxide, tantalum oxide, yttrium oxide, lanthanum oxide, or other transition metal oxide or mixtures thereof. In particular embodiments of the disclosure, the metal oxide comprises aluminum oxide (e.g., Al₂O₃).

In embodiments wherein the selectively deposited dielectric layer comprises depositing an aluminum oxide, the first vapor phase reactant (of sub-step 320) can comprises an aluminum precursor comprising, trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA) or triethyl aluminum (TEA). In some embodiments, an aluminum oxide can be deposited using an aluminum precursor comprising, dimethylaluminum isopropoxide (DMAI).

In embodiments, wherein the exemplary process 150 (FIG. 3) comprises a selective ALD process an aluminum oxide can be selectively deposited by, alternately and sequentially contacting the substrate with a first vapor phase reactant (sub-step 320) comprising, trimethyl aluminum (TMA), dimethylaluminumchloride, aluminum trichloride (AlCl3), dimethylaluminum isopropoxide (DMAI), tris(tertbutyl)aluminum (TTBA), tris(isopropoxide)aluminum (TIPA) or triethyl aluminum (TEA) and a second reactant comprising water (sub-step 330).

In embodiments wherein an aluminum oxide is deposited by a selective ALD process, the process can comprise, alternately and sequentially contacting the substrate with a first vapor reactant (sub-step 320) comprising, trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA) or triethyl aluminum (TEA) and a second reactant comprising water (sub-step 330).

Once the dielectric layer has been selectively deposited to desired thickness or alternatively the selective deposition process has been performed for predetermined time period, or a predetermined number of deposition cycles have been performed the methods of the embodiments of the disclosure may further comprise, selectively removing the passivation layer.

For example, exemplary process 100 (FIG. 1) comprises the process step 160 comprising, selectively removing the passivation whilst maintain the dielectric layer on the surface of the substrate may comprise. In some embodiments, selectively removing the passivation re-exposed the underlying dielectric surface. In some embodiments, selectively removing the passivation layer comprises, contacting the passivation layer with reactive species generated from a plasma formed from a gas comprising hydrogen and argon.

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

What is claimed is:

1. A method for selectively forming a dielectric layer on a metallic surface relative to dielectric surface, the method comprising:
seating a substrate including a metallic surface and a dielectric surface within a reaction chamber;
selectively passivating the metallic surface relative to the dielectric surface;
selectively depositing a passivation layer on the dielectric surface relative to the metallic surface; and
selectively depositing a dielectric layer on the metallic surface relative to the passivation layer.

2. The method of claim 1, further comprising performing a preclean of the substrate prior to selectively passivating the metallic surface relative to the dielectric surface.

3. The method of claim 2, wherein the preclean of the substrate comprises, removing a native oxide from the metallic surface.

4. The method of claim 3, wherein removing the native oxide comprises, contacting the substrate with a vapor phase etchant.

5. The method of claim 4, wherein the native oxide comprises a copper oxide (CuOₓ) and the vapor phase etchant is selected from the group consisting of acetic acid, and hexafluoroacetylacetone (H(hfac)).

6. The method of claim 1, wherein selectively passivating the metallic surface relative to the dielectric surface further comprises, contacting the metallic surface with a silylating agent.

7. The method of claim 6, wherein the silylating agent comprises 1,2-bis(triethoxysilyl)ethane (BTESE).

8. The method of claim 1, wherein selectively forming the passivation layer on the dielectric surface relative to the metallic surface further comprises, performing a plurality of deposition cycles of a molecular layer cyclical deposition process in which the substrate is alternately and sequentially contacted with a first vapor phase organic precursor, and a second vapor phase organic precursor.

9. The method of claim 8, further comprises, performing an etch back process for removing any contaminants from the metallic surface post passivation layer selective deposition.

10. The method of claim 9, wherein the etch back process comprises, contacting the metallic surface with reactive species generated from a plasma formed from a gas comprising hydrogen and argon.

11. The method of claim 1, wherein selectively depositing a dielectric layer on the metallic surface relative to the passivation layer comprise, selectively depositing a metal oxide from vapor phase reactants on the metallic surface relative to the passivation layer.

12. The method of claim 11, wherein the metal oxide comprises aluminum oxide.

13. The method of claim 12, wherein the aluminum oxide is deposited using an aluminum precursor comprising trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA) or triethyl aluminum (TEA).

14. The method of claim 12, wherein the aluminum oxide is deposited using an aluminum precursor comprising dimethylaluminum isopropoxide (DMAI).

15. The method of claim 12, wherein the aluminum oxide is deposited by an ALD process comprising alternately and sequentially contacting the substrate with a first reactant comprising trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA) or triethyl aluminum (TEA) and a second reactant comprising water.

16. The method of claim 12, wherein the aluminum oxide is deposited by a chemical vapor deposition process comprising contacting the substrate with dimethylaluminum isopropoxide (DMAI) and a second reactant comprising water.

17. The method of claim 1, further comprising selectively removing the passivation layer thereby re-exposing the dielectric surface.

18. The method of claim 17, wherein the selectively removing the passivation layer comprises contacting the passivation layer with reactive species generated from a plasma formed from a gas comprising hydrogen and argon.

19. A method for selectively forming an aluminum oxide dielectric layer on a metallic surface relative to dielectric surface, the method comprising:
seating a substrate including a metallic surface and a dielectric surface within a reaction chamber;
contacting the substrate with a silylating agent to selectively passivate the metallic surface relative to the dielectric surface;
selectively depositing a passivation layer on the dielectric surface relative to the metallic surface by performing a plurality of deposition cycles of a molecular layer cyclical deposition process in which the substrate is alternately and sequentially contacted with a first vapor phase organic precursor, and a second vapor phase organic precursor;
contacting the metallic surface with reactive species generated from a plasma formed from a gas comprising one or more of hydrogen and argon, thereby removing any contaminants from the metallic surface;
selectively depositing an aluminum oxide on the metallic surface relative to the passivation layer by contacting the substrate with dimethylaluminum isopropoxide (DMAI) and a second reactant comprising water; and
selectively removing the passivation layer by contacting the passivation layer with reactive species generated from a plasma formed from a gas comprising one or more of hydrogen and argon.
